(19) United States
(12) Patent Application Publication
(10) Pub. No.: US 2025/0117041 A1
(43) Pub. Date: Apr. 10, 2025

(54) CONTROLLER

(71) Applicant: Shenzhen Hailixuan Technology Co., Ltd., Shenzhen (CN)

(72) Inventor: CHANGXI HU, Shenzhen (CN)

(21) Appl. No.: 18/982,831

(22) Filed: Dec. 16, 2024

Related U.S. Application Data
(63) Continuation of application No. PCT/CN2023/091500, filed on Apr. 28, 2023.

(30) Foreign Application Priority Data
Jul. 29, 2022 (CN) 202221987434.1
Apr. 18, 2023 (CN) 202320959378.9

(51) Int. Cl. G06F 1/16; G06F 1/18

(52) U.S. Cl. CPC G06F 1/163; G06F 1/1656; G06F 1/1698; G06F 1/189

(57) ABSTRACT

A controller of a product body is provided, and the controller includes a mounting body suitable for being mounted to the product body, and an operating body. In particular, an electrical connection assembly is arranged on both of the mounting body and the operating body, and configured for detachably conducting a circuit between the mounting body and the operating body; and an auxiliary connection assembly is arranged on both of the mounting body and the operating body, and configured for forming a detachable auxiliary connection between the mounting body and the operating body.

### CROSS-REFERENCE TO RELATED APPLICATIONS

This application is a continuation of International Application No. PCT/CN2023/091500, filed on Apr. 28, 2023, the entire content of which is incorporated herein by reference.

### FIELD OF THE INVENTION

The present invention relates to the technical field of control of health care products, and in particular, to a controller.

### BACKGROUND OF THE INVENTION

Controllers have been widely used for health care products, such as protective gear-type health massage products, and the protective gear-type health massage products are widely used in knee pads, waist pads, shoulder pads, elbow pads, and physical therapy through light therapy, drug therapy, vibration massage and other functions. However, currently, the controller and the product body are integrally designed. On one hand, they need to be connected to the product body through wire plugs, and the wires must always be connected during the application process, resulting that the user should always be near the plug strip and cannot move too much during physical therapy. It is inconvenient to move widely, and it is also easy to be squeezed and loosened, resulting in no electricity or even risk of electric shock. On the other hand, the one-piece design cannot be removed for operation. When using it, if it needs to be adjusted, the entire product needs to be removed. It is troublesome to remove it from the product body for adjustment and then wear it on the corresponding part of the body, and it is inconvenient to operate.

So that, there is an urgent need to improve the controllers in existing health care products so that they can be used more conveniently for health care physiotherapy.

### SUMMARY OF THE INVENTION

### (1) Solved Technical Problem

To solve the above problems, the present invention provides a detachable controller.

### (2) Technical Solution

To achieve the above objectives, the present invention provides the following technical solution:

In one aspect, a controller of a product body is provided, and the controller includes a mounting body suitable for being mounted to the product body, and an operating body. In particular, an electrical connection assembly is arranged on both of the mounting body and the operating body, and configured for detachably conducting a circuit between the mounting body and the operating body; and an auxiliary connection assembly is arranged on both of the mounting body and the operating body, and configured for forming a detachable auxiliary connection between the mounting body and the operating body.

In another aspect, another controller of a product body is provided, and the controller includes a mounting body suitable for being mounted to the product body, and an operating body. In particular, a detachable connection assembly arranged on both of the mounting body and the operating body, and configured for forming a detachable connection between the mounting body and the operating body, and forming a detachably conducting a circuit between the mounting body and the operating body.

In further another aspect, a controller of a product body is provided, and the controller includes a mounting base suitable for being mounted to the product body, and a controller main body. In particular, the mounting base includes a plurality of first magnetic buckles and a first slider, and the plurality of first magnetic buckles are electrically connected to a circuit in the product body. The controller main body includes a plurality of second magnetic buckles electrically connected to a control circuit of the controller main body, and a second slider. The first magnetic buckles and the second magnetic buckles are magnetically connected, and the first slider and the second slider are engaged with each other.

### (3) Beneficial Effects

Compared with the prior art, the present invention brings the following beneficial effects:
(1) The controller, which integrates a mounting body, an operating body and a power supply element, and is detachably electrically connected to the product body, so that the product body does not require wires during application and is easy to move.
(2) The controller, the operating body of which is detachably connected to the product body, making it easy to remove and adjust parameters, and the operation is convenient. The operation of the product body is controlled by ting the operating body, thereby exerting the effect of health care and physical therapy.
(3) The controller, which reasonably arranges the electrical connection points with the magnetic connection components, buckle connection components and slide rail connection components, thereby reducing the number of contact points and ensuring the stability and safety of the connection, helping extending the service life of the product.
(4) The controller, which has multiple connection methods, which not only facilitates assembly but also ensures the stability of the connection. The user can perform other activities at the same time during physical therapy without worrying about the accident of the controller falling, thus it will not affect the user's normal work and life.
(5) The controller, which is equipped with a wireless communication module to realize wireless remote control through bluetooth, infrared, WiFi, etc., which facilitates timely adjustment of various parameters without removing it from the product body and ensures continuous use, and adjust the parameters according to the situation to meet the needs of more people.
(6) The controller, which can be installed in various health care products and has a wide range of applications.
(7) The controller, which has a variety of electrical connection methods, which not only ensures the stability between the controller and the product body, but also ensures the stability of the power supply and prevents interruptions.

### BRIEF DESCRIPTION OF THE DRAWINGS

FIG. 1 is a schematic structural view of a controller according to a first embodiment of present invention.

FIG. 2 is a partially exploded view of the controller of FIG. 1.

FIG. 3 shows an application of the controller of FIG. 1.

FIG. 4 shows another application of the controller of FIG. 1.

FIG. 5 is a schematic structural view of a controller according to a second embodiment of present invention.

FIG. 6 shows an application of the controller of FIG. 5.

FIG. 7 shows another application of the controller of FIG. 5.

FIG. 8 is a schematic structural view of a controller according to a third embodiment of present invention.

FIG. 9 is a schematic structural view of a controller according to a fourth embodiment of present invention.

FIG. 10 is an enlarged view of the A part of FIG. 9.

FIG. 11 a schematic structural view of a controller according to a fifth embodiment of present invention.

FIG. 12 is another schematic structural view of the controller of FIG. 11.

FIG. 13 is an enlarged view of a first slider on the controller of FIG. 11.

FIG. 14 is an enlarged view of a second slider on the controller of FIG. 12.

### DETAILED DESCRIPTION OF PREFERRED EMBODIMENTS

The following will provide a clear and complete description of the technical solution in the embodiments of the present invention, in conjunction with the accompanying drawings. Obviously, the described embodiments are only a part of the embodiments of the present invention, not all of them. Based on the embodiments in the present invention, all other embodiments obtained by ordinary technicians in the art without creative labor fall within the scope of protection of the present invention.

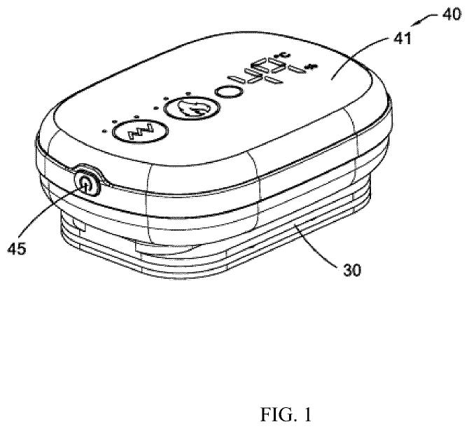

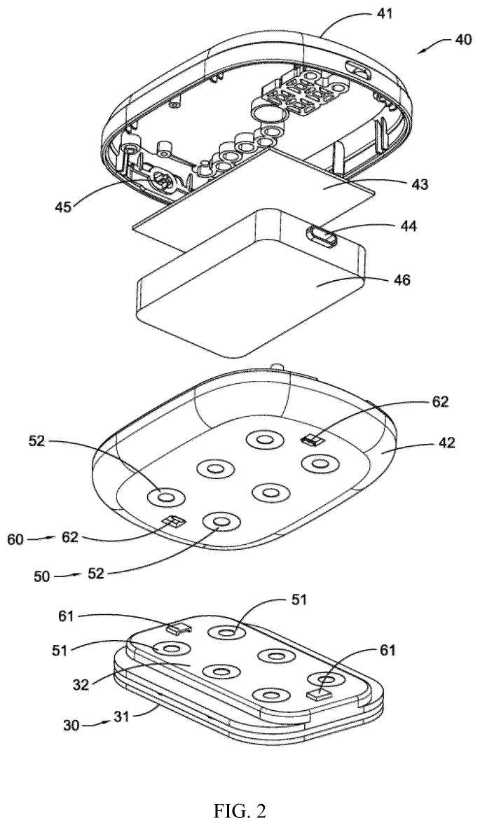

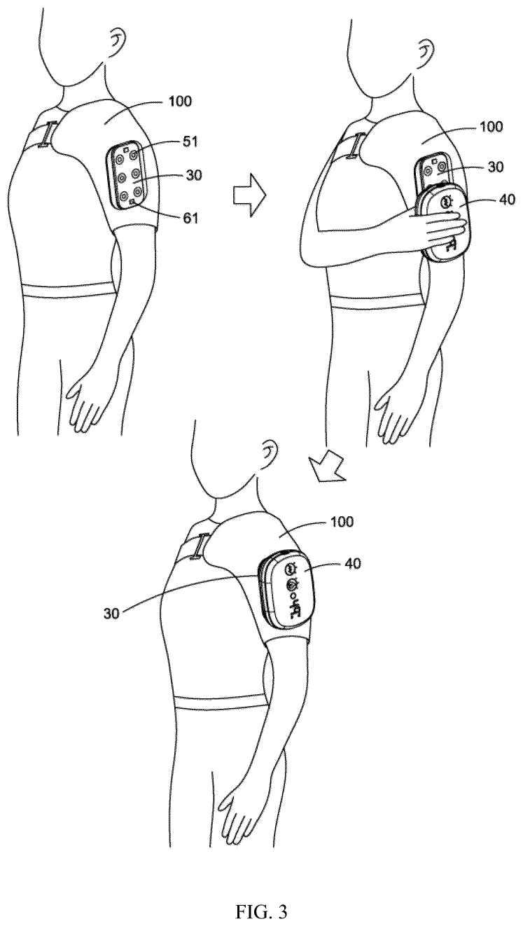

Referring to FIGS. 1 and 2, a controller according to a first preferred embodiment of the present invention is schematically illustrated. In this embodiment, the controller includes a mounting body 30, an operating body 40, an electrical connection component and an auxiliary connection component. The mounting body 30 is suitable for being fixedly connected to a product body 100 (see the references 100 on FIG. 3), and is connected to the product body 100. The circuit module of the product body 100 is electrically conductive, and the operating body 40 is detachably electrically connected to the mounting body 30 through the electrical connection component and the auxiliary connection component.

The operating body 40 includes a power supply element 46. The power supply element 46 is disposed inside the operating body 40. The power supply element 46 supplies power to the product body 100 so that the product body 100 can be applied to shoulder and knee joints. No wires are needed during the physical therapy of the elbow, waist and waist, and the physical therapy parameters that are suitable for the user and the used part are set through the operating body 40 to control the work of the product body 100.

The mounting body 30 includes a first mounting surface 31 and a second mounting surface 32, and the first mounting surface 31 is configured to be connected to the product body 100. The mounting body 30 is electrically connected to the product body 100 through the first mounting surface 31. The second mounting surface 32 is opposite to the first mounting surface 31, and the second mounting surface 32 is suitable for electrical connection with the operating body 40.

The operating body 40 has an operation interface 41, a connection interface 42, a chip 43, a power interface 44 and a switch 45, The chip 43 is installed on in a cavity formed between the operation interface 41 and the connection interface 42. The power interface 44 and the switch 45 are disposed on a side of the operating body 40 and are electrically connected to the power supply element 46.

When the operating body 40 is connected to the mounting body 30, the connection interface 42 is adapted to fit the second mounting surface 32, and the operating body 40 is detachably electrically connected to the mounting body 30 through an electrical connection between the connection interface 42 and second mounting surface 32.

The power supply element 46 can be charged through the power interface 44, thereby powering the product body 100, so that the product body 100 does not need to be connected to wires when working, making movement more convenient, and controls the startup and turn off of the product body 100 through the switch 45.

In present application, the controller further includes a preset program module, which is provided on the operating body 40. In this embodiment, the operation interface 46 and the chip 43 form a preset program module. The physiotherapy parameters for the product body 100 working are set through the preset program module, and can be adjusted at any time to make the product body conform to the needs of the user.

Specifically, the user is suitable to set parameters through the operation interface 41, where the parameters are preset in the chip 43, and the chip 43 has a memory function, so that after the physical therapy parameters are set, and after the operating body 40 is installed on the mounting body 30, the product body 100 can work according to the preset parameters.

When the parameters need to be readjusted, the operating body 40 can be removed and readjusted without removing the entire product body 100 and the mounting body 30. Therefore, removal and installation of the operating body 40 are relatively simple and convenient.

The electrical connection component in this application is a detachable electrical connection component. In this embodiment, the controller further includes at least one magnetic connection component 50, and the magnetic connection component 50 is the detachable electrical connection component. The auxiliary connection component is implemented as at least one buckle connection component 60, and the magnetic connection component 50 and the buckle connection component 60 are both disposed on the mounting body 30 and the operating body 40 to allow the mounting body 30 and the operating body 40 to be detachably electrically connected.

Each of the magnetic connection components 50 includes a first magnetic connector 51 and a second magnetic connector 52. The first magnetic connector 51 is disposed on the second mounting surface 32 of the mounting body 30, and the first magnetic connector 51 is electrically connected to the circuit structure inside the mounting body 30 to connect the circuit module inside the product body 100.

A plurality of the first magnetic connectors 51 are spaced apart on the second mounting surface 32 of the mounting body 30. In this embodiment, there are six first magnetic connectors 51 arranged in three rows and two columns on the second mounting surfaces 32 of the mounting body 30, thereby presenting multi-point connections to ensure stable connection and conduction.

The number of the second magnetic connectors 52 and the arrangement position thereof correspond to the first magnetic connectors 51. The second magnetic connectors 52 are disposed on the connection interface 42 of the operating body 40 and are connected to the power supply element 46 and the chip 43.

That is, the magnetic connection component 50 forms the detachable electrical connection component in this embodiment, wherein the first magnetic connector 51 is electrically connected to the circuit structure inside the mounting body 30, and the second magnetic connector 52 is electrically connected to the circuit structure inside the operating body 40. The first magnetic connector 51 and the second magnetic connector 52 are made of conductive metal material. When the second magnetic connector 52 is connected to the first magnetic connector 51 through magnetic attraction, the circuit between the two can also be connected and conduct electricity, thereby supplying power to the product body 100. That is to say, after conduction, power can be supplied to the heating device, vibration device and other physical therapy equipment installed in the product body 100 to control the product body 100 to perform heating, vibration and other physical therapy.

The first magnetic connector 51 and the second magnetic connector 52 are implemented as protrusions and grooves in this embodiment, but may also be implemented as magnetic buckles or other magnetic attraction methods.

The buckle connection component 60 includes a connection slot 61 and a connection buckle 62, which are respectively provided on the second mounting surface 32 of the mounting body 30 and the connection interface 42 of the operating body 40. The connection buckle 62 matches the connection slot 61.

Wherein two of the connection slots 61 are provided at both ends of the first magnetic connection member 51, and two of the connection buckles 62 are provided at both ends of the second magnetic connection member 52, such corresponding arrangement facilitates matching connections.

The plurality of magnetic connection components 50 provided on the mounting body 30 and the operating body 40 forms the magnetic connection assembly, and such magnetic connection components 50 have the same specifications. The buckle connection components 60 provided on both ends of the mounting body 30 and the operating body 40 forms the auxiliary connection assembly, and the two connection slots 61 are the same, the two connection buckles 62 are the same. Such same arrangements makes the two ends of the operating body 40 and the two ends of the mounting body 30 arbitrarily matched, and there is no need to consider the installation direction during installation, making the installation more convenient.

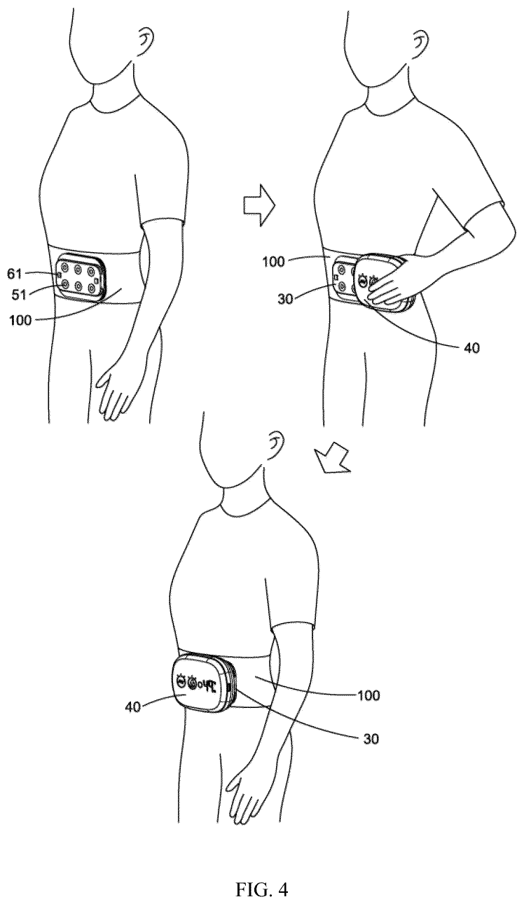

Referring to FIG. 3 and FIG. 4, application examples of the controller of the present invention are shown. The mounting body 30 is provided in the product body 100, and the operating body 40 is detachably installed on the mounting body 30, and the two are connected through the magnetic connection component 50 and the buckle connection component 60.

Before use, the user can first remove the operating body 40 and wear the product body 100 with the mounting body 30 on the shoulder, waist, elbow, knee joint, etc. The location of use is not limited by the drawings. The user then sets corresponding parameters by operating the operating body 40. After successfully setting the parameters, the user installs the operating body 40 on the mounting body 30 to conduct electricity through the electrical connection between the magnetic connection components 50. This is easy to install and easy to operate.

Due to the use of the buckle connection component 60, the operating body 40 is firmly connected to the mounting body 30. At this time, the user can do housework, read, exercise, etc. without worrying that the operating body 40 will fall.

Compared with traditional one-piece products, users can remove the operating body 40 to set parameters instead of reaching their shoulders and turning their heads to adjust. This product makes the adjustment process more convenient for users.

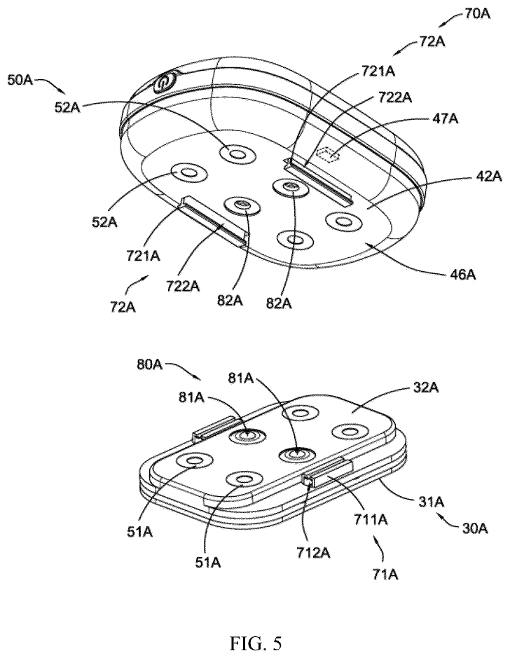

Referring to FIG. 5, a controller according to a second embodiment of the present invention is shown. In this embodiment, the controller also includes a mounting body 30A, an operating body 40A, an electrical connection component and an auxiliary connection component. The mounting body 30A and the operating body 40A are detachably electrically connected through the electrical connection component and the auxiliary connection component.

Wherein the electrical connection component is implemented as a magnetic connection component 50A and an abutting bead connection component 80A, and the auxiliary connection component is implemented as a slide rail connection component 70A.

The operating body 40A includes a power supply element 46A, and the power supply element 46A is disposed inside the operating body 40A and connected to the magnetic connection component 50A. The magnetic connection component 50A and the slide rail connection component 70A are provided on both the mounting body 30A and the operating body 40A. The operating body 40A is detachably electrically connected to the mounting body 30A through the connection of the magnetic connection component 50A, and then through the slide rail connection component 70A, the connection between the operating body 40A and the mounting body 30A are more stable and prevents falling.

The mounting body 30A is fixed to product body 100 by the first mounting surface 31A. The second mounting surface 32A of the mounting body 30A and the connection interface 42A of the operating body 40A can be modified.

Specifically, the magnetic connection component 50A includes a first magnetic connector 51A and a second magnetic connector 52A. The first magnetic connector 51A and the second magnetic connector 52A matches with each other, and are made of metal, and the two are connected to conduct a circuit. In present embodiment, the number of the first magnetic connectors 51A is four, and the first magnetic connectors 51A are arranged in two parallel rows at both ends of the mounting body 30A. The number of the second magnetic connectors 51A is four, and the second magnetic connectors 51A are arranged in two parallel rows at both ends of the operating body 40A, and are connected to the first magnetic connectors 51A in a matching manner.

The abutting bead connection component 80A includes a plurality of mounting grooves 81A and a plurality of abutting beads 82A. The mounting grooves 81A are provided on the mounting body 30A and located in the middle of the first magnetic connectors 51A; the abutting beads 82A are provided on the operating body 40A, located in the middle of the second magnetic connector 52A, and are connected to the mounting grooves 81A in a matching manner.

The abutting bead 82A is nearly spherical, and the mounting groove 81A is also a nearly spherical groove. The abutting bead82A is suitable for sliding into the mounting groove 81A, which facilitates convenient matching and connection by the user. Moreover, the abutting bead82A is slightly elastic and can be rolled and extruded into the interior of the mounting groove 81A, thereby ensuring the firmness between the operating body 40A and the mounting body 30A while also facilitating separation. In addition, due to the tight connection of the abutting bead connection component 80A, it is also helpful to prevent misalignment and power outage caused by factors such as large movements, thus ensuring the continuous operation of the product.

The first magnetic connector 51A is disposed on the mounting body 30A and is connected to the circuit structure of the mounting body 30A and the circuit module in the product body 100; the second magnetic connector 52A is disposed on the operating body 40A is electrically connected to the circuit, the chip and power supply element 46A inside the operating body 40A. When the second magnetic connector 52A is connected to the first magnetic connector 51A, power can be supplied to the product so that the product can operate normally.

That is to say, after the second magnetic connector 52A is connected to the first magnetic connector 51A, on one hand, the operating body 40A is connected to the mounting body 30A, and on the other hand, the entire controller and the product body 100 can be connected, and the circuit between the bodies is thus connected, enabling the product body 100 to work according to the parameters set in advance for the operating body 40A.

Preferably, the abutting bead connection component 80A is also conductive. On one hand, it connects the operating body 40A to the mounting body 30A, and on the other hand, it can conduct the circuit between the operating body 40A and the mounting body 30A.

In order to ensure the firmness of the connection between the operating body 40A and the mounting body 30A, the auxiliary connection component in this embodiment is implemented as a slide rail connection component 70A, wherein the slide rail connection component 70A includes a first The slide rail connector 71A and a second slide rail connector 72A. The number and size of the second slide rail connector 72A match with those of the first slide rail connector 71A, and they are arranged correspondingly, with the two can be connected separately.

The two first slide rail connectors 71A are longitudinally disposed on the mounting body 30A, and are located on both sides of the first magnetic connector 51A. The second slide rail connectors 72A are longitudinally disposed on the operating body 40A, and are located on both sides of the second magnetic connector 52A.

In this embodiment, the first slide rail connecting member 71A includes two protruding edges 711A and a slide groove 712A. The slide groove 712A is disposed between the two protruding edges 711A. The bottoms of the protruding edges 711A are connected to the mounting body30A, and are suitable for a design that is integrally formed with the mounting body 30A.

The second slide rail connector 72A includes two extending edges 721A and a slide rail 722A. The two extending edges 721A extend outward from both sides of the slide rail 722A and are suitable for being integrally formed with the slide rail 722A.

When the second slide rail connector 72A is connected to the first slide rail connector 71A, the slide rail 722A enters the slide groove 712A, and the extending edge 721A is located at a lower side of the protruding edge 711A, and fit the lower side of the protruding edge 711A and move along the protruding edge 711A, so that the slide rail 722A is firmly located inside the slide groove 712A, thereby firmly connecting the operating body 40A to the mounting body 30A.

When the operating body 40A is connected to the mounting body 30A, the connection is made in two ways, one is the connection between the second magnetic connector 52A and the first magnetic connector 51A, and the other is the connection between the second slide rail connector 72A and the first slide rail connector 71A. The first magnetic connector 51A and the second magnetic connector 52A are made of conductive materials, and after the two are connected, they can conduct electricity.

The connection method of this embodiment not only ensures the electrical connection between the operating body 40A and the mounting body 30A, but also ensures the stability of the connection between the two. During the application process, the patient can do various movements without worrying that the operating body 40A will fall.

The preset program module inside the operating body 40A also includes a wireless communication module 47A. The wireless communication module 47A is disposed inside the operating body 40A, and the controller can be controlled through the wireless communication module 47A. In electronic devices such as mobile phones, tablets, and computers, users can control the operating body 40A through mobile phones, tablets, computers, etc., and set and adjust its parameters. Especially during the application process, if the physical therapy parameters need to be changed, for example, temperature, vibration frequency, time, etc. can only be adjusted through electronic devices, which is simple and convenient.

It is worth mentioning that the wireless communication module 47A can realize the communication connection between the electronic device and the controller through wireless communication methods such as bluetooth, infrared, and WiFi, thereby achieving the purpose of wireless remote control and controlling the product body 100 in a simpler way.

In this embodiment, the operating body 40A can be installed from both ends of the mounting body 30A. That is to say, when the operating body 40A is installed on the mounting body 30A, there is no need to consider the direction. Both ends of the main body 40A can be installed along the mounting body 30A, which brings great convenience to the user. The user can easily and quickly install the operating body 40A on the mounting body 30A.

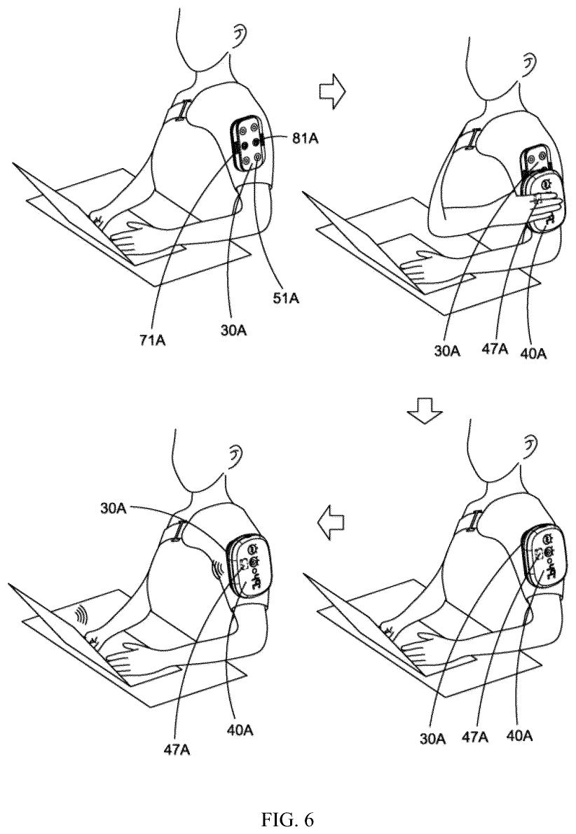

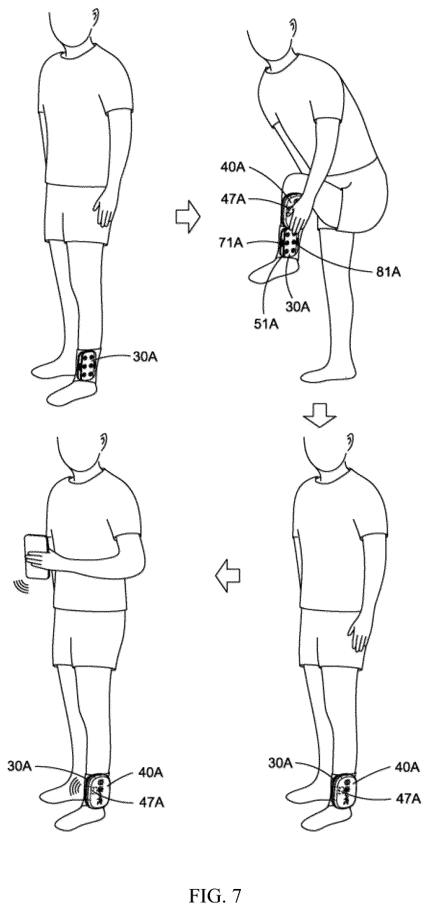

Referring to FIG. 6 and FIG. 7, the application of the controller provided in this embodiment is combined with the product body 100 (see the reference on FIG. 3). The mounting body 30A is fixed in the product body 100 and is electrically connected to the circuit module inside the product body 100. During use, the user first wears the product body 100 with the mounting body 3A on the area to be treated, such as shoulders, ankles, elbows, waist, knees, etc., and then holds the operating body 40A to each area. The physical therapy parameters are set, including temperature, time, vibration frequency, etc., and then the operating body 40A is installed on the mounting body 30A, so that the second magnetic connector 52A connects the first magnetic connector 51A to form an electrical connection, the second slide rail connector 72A is connected to the first slide rail connector 71A.

Since the operating body 40A and the mounting body 30A can be firmly connected, the user can read, do housework, exercise or work during the physical therapy process. When it is necessary to adjust the physical therapy parameters, on the one hand, the mounting body 40A can be removed, adjusted through the operating interface 41A, and then installed after adjustment; on the other hand, the wireless communication module 47A can be connected through electronic devices such as mobile phones and tablets to form a wireless connection for adjustment.

For example, when the user is working during physical therapy, if they need to adjust the physical therapy parameters, they can do so directly through the computer they are working on. There is no need to take it off, bend down, turn the head, etc., and it will not affect the work, the physical therapy process will not be interrupted, which is very convenient.

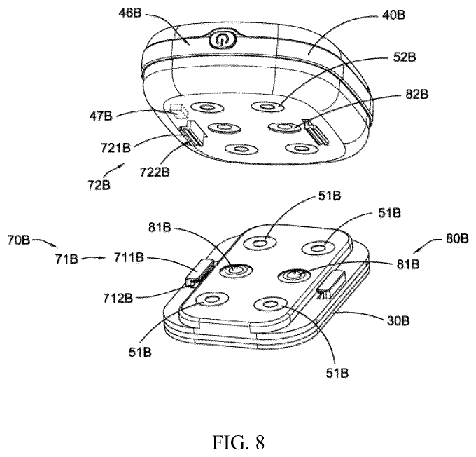

Referring to FIG. 8, which is a schematic structural diagram of a controller according to the third preferred embodiment of the present invention. In this embodiment, the controller includes a mounting body 30B, an operating body 40B, a magnetic connection component 50B, a slide rail connection component 70B and an electrical connection component 80B, wherein the magnetic connection component 50B and the slide rail connection components 70B are both disposed on the mounting body 30B and the operating body 40B, so that the operating body 40B is detachably connected to the mounting body 30B through the magnetic connection component 50B and the slide rail connection component 70B. The electrical connection component 80B is also provided on the mounting body 30B and the operating body 40B. The operating body 40B includes a power supply element 46B, and the power supply element 46B is arranged inside the operating body 40B, wherein the electrical connection component 80B is connected to the power supply element 46B to provide power to the controller and the product body 100 connected to the controller, so that the product body 100 can operate normally.

Specifically, in this embodiment, the mounting body 30B is fixed to the product body 100 (see the reference on FIG. 3) and connected to the circuit module in the product body 100.

The magnetic connection assembly 50B includes a first magnetic connector 51B and a second magnetic connector 52B that match each other and are respectively provided on the mounting body 30B and the operating body 40B, wherein the first magnetic connector 51B and the second magnetic connector 52B are detachably connected through magnetic attraction, thereby allowing the operating body 40B to be detachably connected to the mounting body 30B.

In this embodiment, the magnetic connection component 50B does not have a conductive function and is not connected to the circuit structure.

The slide rail connection component 70B includes a first slide rail connector 71B and a second slide rail connector 72B, which are respectively provided on the mounting body 30B and the operating body 40B to further firmly connect the operating body 40B to the mounting body 30B.

Specifically, the first slide rail connector 71B includes a guide edge 711B and a slide groove 712B. The guide edge 711B extends outward from the mounting body 30B and forms a gap between the guide edge 711B and the mounting body 30B. The slide groove 712B has one side and top surface closed by the guide edge 711B, the bottom surface of the slide groove 712B is closed by the mounting body 30B, and other edges of the slide groove 712B are in communication with outside.

The second slide rail connector 72B includes a slide rail 721B and a guide groove 722B. One side of the slide rail 721B extends outward from the operating body 40B, and forms the guide groove 722B between the slide rail 721B and the operating body 40B. The guide groove 722B matches the guide edge 711B, and the slide rail 721B matches the slide groove 712B, so that the slide rail 721B moves along the slide groove 712B, and the guide edge 711B By moving along the guide groove 722B, the second slide rail connector 72B can be connected to the first slide rail connector 71B, and the operating body 40B and the mounting body 41B can be firmly connected.

The structure of the electrical connection component 80B in this embodiment is the same as the abutting bead connection component 80A in the above embodiment, and it is also a detachable electrical connection component. In this embodiment, the electrical connection component 80B includes a first electrical connector 81B and a second electrical connector 82B, which are respectively provided on the mounting body 30B and the operating body 40B, to form electrical connections between them.

The first electrical connector 81B is disposed on the mounting body 30B and is located between the plurality of first magnetic connectors 51B. The first electrical connector 81B is electrically connected to circuit structure of the mounting body 30B, and circuit modules inside the product body 100.

The second electrical connector 82B is provided on the operating body 40B and is electrically connected to the chip 43B and the power supply element 46B. When the second electrical connector 82B is connected to the first electrical connection member 81B, the circuit can be turned on through switch control.

In this embodiment, the first electrical connector 81B and the second electrical connector 82B are respectively implemented as two sets of matching protrusions and grooves, and when the first electrical connector 81B and the second electrical connector 82B are connected, the electrical properties of the two are connected to conduct the circuit.

When the first slide rail connector 71B is connected to the second slide rail connector 72B, the first magnetic connector 51B is connected to the second magnetic connector 52B, and at the same time, the first electrical connector 81B is connected to the second electrical connector 82B, thereby detachably electrically connecting the operating body 40B to the mounting body 30B.

In this embodiment, the operating body 40B further includes a wireless communication module 47B. The wireless communication module 47B is disposed inside the operating body 40B and is communicatively connected to the chip 43B. The wireless communication module 47B is communicatively connected to the chip 43B. The module 47B is further connected to the user's electronic devices such as mobile phone, computer, tablet and others. The wireless communication module 47B realizes the communication connection between the electronic device, the controller and the product body 100, so that the product body 100 and the controller can be operated through the electronic devices.

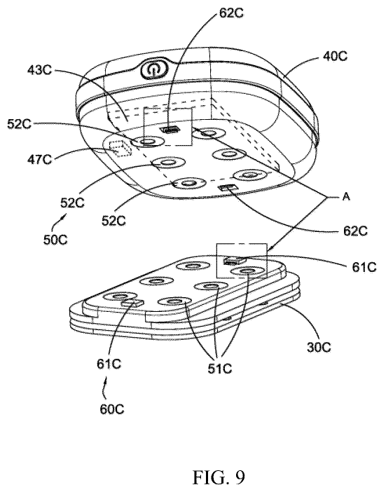

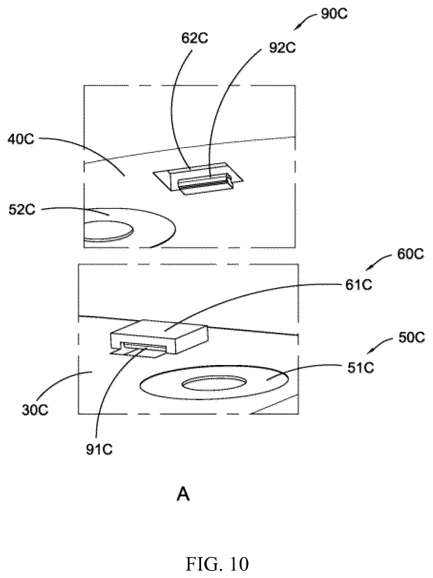

Referring to FIGS. 9 and 10, a controller according to a fourth preferred embodiment of the present invention is shown. In this embodiment, the controller includes a mounting body 30C, an operating body 40C, a magnetic connection component 50C, a buckle connection component 60C and an elastic connection component 90C. The operating body 40C includes a power supply element 46C, the power supply element 46C is installed inside the operating body 40C and is electrically connected to the elastic connection component 90C. The magnetic connection component 50C and the buckle connection component 60C are both provided on the mounting body 30C and the operating body 40C, so that the operating body 40C is detachably electrically connected to the mounting body 30C.

Specifically, the mounting body 30C is pre-fixed to the product body 100 (see the reference on FIG. 3) and is electrically connected to the product body 100.

The magnetic connection component 50C realizes the first reconnection, and the buckle connection component 60C realizes the second reconnection, making the connection between the mounting body 30C and the operating body 40C more secure. The elastic connection component 90C is a detachable electrical connection component, and the buckle connection component 60C is an auxiliary connection component. The operating body 40C is detachably electrically connected to the mounting body 30C through the buckle connection component 60C and the elastic connection component 90C.

The magnetic connection assembly 50C includes a first magnetic connector 51C and a second magnetic connector 52C that match each other and are respectively provided on the mounting body 30C and the operating body 40C, wherein the first magnetic connector 51C and the second magnetic connector 52C are detachably connected through magnetic attraction, thereby allowing the operating body 40C to be detachably connected to the mounting body 30C.

The magnetic connection component 50C in this embodiment does not have a conductive function and is not connected to the circuit structure.

The buckle connection component 60C includes a plurality of connection slots 61C and a plurality of connection buckles 62C, wherein the connection buckles 62C match the connection slots 61C, and the two are detachably connected.

The two connection slots 61C are provided on the mounting body 30C and are located at both ends of the first magnetic connector 51C. The mounting body 30C extends outward to form a protrusion with a groove, wherein the connection slots 61C is located between the protrusion and the mounting body 30C and communicates with the outside.

The two connection buckles 62C are arranged on the connection interface 42C of the operating body 40C, enter the interior of the connection slots 61C through the opening of the connection slots 61C, and then be connected to the connection slot 61C.

The elastic connection component 90C includes a plurality of first elastic connection parts 91C and a plurality of second elastic connection parts 92C, where the two first elastic connection parts 91C are respectively disposed inside the two connection slots 61C, and the two second elastic connecting members 92C are respectively provided inside the two connecting buckles 62C.

When the connection buckle 62C is connected to the connection slot 61C, the second elastic connection member 82C presses the first elastic connection member 91C, that is, the second elastic connection member 92C and the first elastic connection member 91C are connected to the connection buckle 62C. The elastic connecting parts 91C are pressed against each other, so that the second elastic connecting part 92C is connected to the first elastic connecting part 91C.

The first elastic connector 91C is electrically connected to the circuit structure inside the mounting body 30C and the circuit module inside the product body 100. The second elastic connector 92C is electrically connected to the chip 43C. After the first elastic connector the connecting member 91C is connected to the second elastic connecting member 92C, the circuit can be connected, so that the operating body 40C is electrically connected to the mounting body 30C.

That is to say, in this embodiment, the first elastic connection member 91C and the second elastic connection member 92C are both made of metal spring pieces. The connection and extrusion make the first elastic connection member 91C electrically connected to the second elastic connection member 92C. After the connection buckle 62C and the connection slot 61C are separated, the circuit can be disconnected.

Therefore, under the action of the magnetic connection component 50C and the buckle connection component 60C, the operating body 40C is firmly connected to the mounting body 30C, and under the action of the elastic connection component 90C, the operating body 40C is firmly connected to the mounting body 30C. The operating body 40C can be electrically connected to the mounting body 30C, thereby supplying power to the product body and controlling the product body 100 so as to be worn on corresponding parts for physical therapy.

In this embodiment, the default program module inside the operating body 40C may also include a wireless communication module 47C, which is installed inside the operating body 40C. Through the wireless communication module 47C, the controller and Wireless communication between mobile phones and other electronic devices.

It is worth mentioning that the power interface can charge the power supply element 46C, can also be directly connected to a power supply port such as a socket, and can also provide electrotherapy functions to the product by connecting wires.

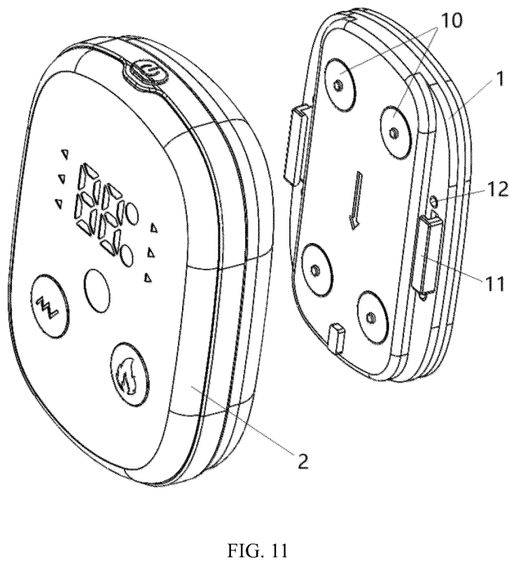

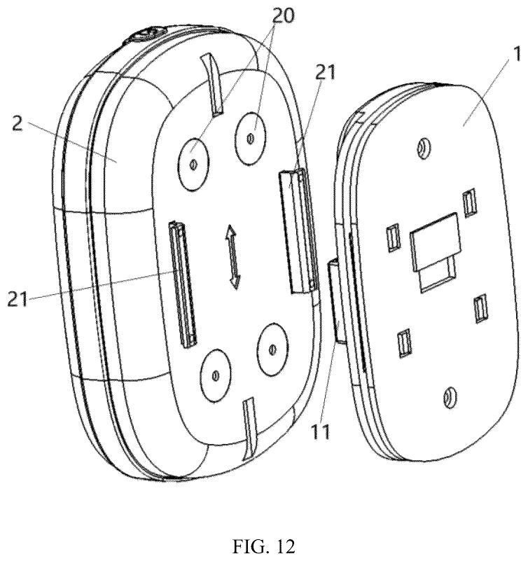

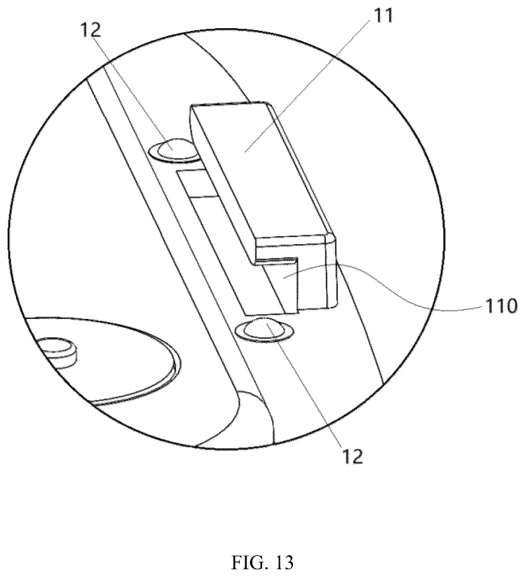

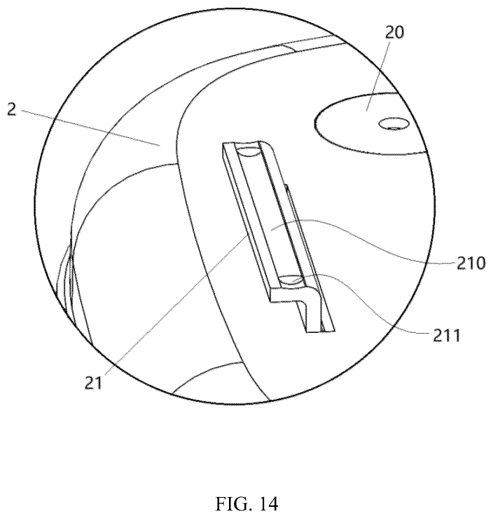

Referring to FIGS. 11 to 14, a controller according to a fifth embodiment is shown. The controller includes a mounting base 1, and a controller main body 2. The mounting base 1 is installed on a product body (see the reference 100 on FIG. 3), the mounting base 1 is provided with a plurality of first magnetic buckles 10 and a first slider 11, and the plurality of first magnetic buckles 10 are electrically connected to the functional modules in the product body.

The controller main body 2 has a control board therein with control circuit. The controller body 2 further includes a plurality of second magnetic buckles 20 that are electrically connected to the control board. The first magnetic buckles 10 and the second magnetic buckles 20 are magnetically connected. The controller main body 2 is also provided with a second slider 21, and the first slider 11 and the second slider 21 are engaged with each other.

The controller is configured for controlling the product body, which may be protective gear massagers, such as wearable waist massagers, leg massagers, etc. The mounting base 1 is installed on the product body, and the controller main body 2 and the mounting base 1 not only form a magnetic connection through the first magnetic buckle 10 and the second magnetic buckle 20, but also have the engagement through the first slider 11 and the second slider 21, so that the control board in the controller main body 2 can control the product body, and the connection structure of the controller is more stable, preventing the controller from falling when the user wears the product body with the controller for exercise.

Furthermore, regarding the fastening structure between the mounting base 1 and the controller main body 2, in this embodiment, the first slider 11 is provided with a sliding groove 110, and a protruding block 12. The protruding block 12 is along a length direction of the first slider 11, either inside or outside the sliding groove 110.

The second slider 21 is inserted into the sliding groove 110 and resists the protruding block 12. Specifically, both the first slider 11 and the second slider 21 are arranged in an “L” shape structure, the first slider 11 and the second slider 21 are arranged in opposite directions, and after the first slider 11 and the second slider 21 are engaged with each other, the second slider 21 presses against the protruding block 12, and the pressure of the protruding block 12 on the second slider 21 makes the second slider 21 tightly press against the first slider 11 to realize the snap connection between the two. Both the first slider 11 and the second slider 21 have a certain degree of elastic deformation ability. After the second slider 21 is pressed by the protruding block 12, both the first slider 11 and the second slider 21 deform slightly. Their elastic reset forces act together on the clamping process to make the first slider 11 and the second slider 21 more firmly clamped.

Furthermore, each functional item in the massager product body requires the control board in the controller main body 2 to form an electrical control contact with the corresponding functional module in the massager product body. Therefore, in this embodiment, the protruding block 12 is also connected with the corresponding functional module in the massager product body. The functional modules are electrically connected, the second slider 21 is made of metal and is electrically connected to the control board, and the first slider 11 is made of plastic. The protruding block 12 not only has a snapping function, but also serves as electrical contacts, improving the functional control capabilities of the controller main body 2.

Furthermore, a groove 210 is provided on the side of the second slider 21 facing the protruding block 12. The groove 210 is along the length direction of the second slider 21, and the protruding block 12 can resist the groove 210. The arrangement of the groove 210 makes it easier for the protruding block 12 to protrude into and press against the side of the second slider 21 facing the mounting base 1 during the sliding insertion of the second slider 21 into the slide groove 110.

Furthermore, the second slider 21 is also provided with a slot 211 corresponding to the protruding block 12, so that the protruding block 12 can be inserted into the slot 211. Because when the second slider 21 presses against the protruding block 12, the second slider 21 has elastic deformation. When the protruding block 12 moves to the position of the slot 211, the elastic reset ability of the second slider 21 causes the protruding block 12 to snap into the slot 211. The position of the second slider 21 is fixed until the user exerts external force on the controller main body 2, causing the second slider 21 to overcome the elastic force and deform and arch, so that the protruding block 12 can be separated from the slot 211.

Those skilled in the art should understand that the embodiments of the present invention shown in the above description and drawings are only examples and do not limit the present invention. The object of the present invention has been completely and effectively achieved. The functional and structural principles of the present invention have been shown and described in the embodiments, and the implementation of the present invention may have any variations or modifications without departing from the principles.

What is claimed is:

1. A controller of a product body, comprising:
a mounting body suitable for being mounted to the product body;
an operating body;
an electrical connection assembly arranged on both of the mounting body and the operating body, and configured for detachably conducting a circuit between the mounting body and the operating body; and
an auxiliary connection assembly arranged on both of the mounting body and the operating body, and configured for forming a detachable auxiliary connection between the mounting body and the operating body.

2. The controller according to claim 1, wherein the electrical connection assembly or the auxiliary connection assembly includes at least one magnetic connection component comprising a first magnetic connector and a second magnetic connector respectively disposed on the mounting body and the operating body, wherein the second magnetic connector and the first magnetic connector are capable of being magnetically attracted and being detachable from each other.

3. The controller according to claim 1, wherein the auxiliary connection assembly includes at least one buckle connection component comprising a connection slot and a connection buckle, respectively disposed on the mounting body and the operating body, wherein the connection slot and the connection buckle are capable of being detachably connected.

4. The controller according to claim 1, wherein the auxiliary connection assembly includes at least one slide rail connection component comprising a first slide rail connector and a second slide rail connector respectively provided on the operating body and the mounting body, wherein the first slide rail part and the second slide rail part are capable of being detachably connected.

5. The controller according to claim 4, wherein the first slide rail connector includes two protruding edges and a slide groove, and the two protruding edges extend outward from the mounting body and cooperatively form the slide groove; and the second slide rail connector includes two extending edges and a slide rail, and the slide rail is formed by extending outward from the operating body, the extending edges are provided on both ends of the slide rail, wherein the extending edge and the slide rail are adapted to move along the slide groove to connect the operating body to the mounting body.

6. The controller according to claim 4, wherein the first slide rail connector includes a guide edge and a slide groove, the guide edge is connected to the mounting body, and the slide groove is formed between the guide edge and the mounting body; the second slide rail connector includes a slide rail and a guide groove, the slide rail is connected to the operating body, and the guide groove is formed between the slide rail and the operating body, the slide rail is adapted to move along the slide groove, and the guide edge is adapted to move along the guide groove to connect the operating body to the mounting body.

7. The controller according to claim 1, wherein the operating body includes a chip, a power interface and a power supply element, the power supply element is electrically connected to the chip, the power interface and the electrical connection assembly to provide electrical energy to the controller and control the controller, the chip has a memory function so that after the physical therapy parameters are set, and the operating body is installed on the mounting body, the product body can work according to the preset parameters.

8. The controller according to claim 7, wherein the operating body further includes a wireless communication module, the wireless communication module is connected to the chip and is suitable for wireless communication with an electronic device.

9. The controller according to claim 2, wherein the magnetic connection component is adapted to conduct electricity, the first magnetic connector is electrically connected to a circuit structure inside the mounting body, and the second magnetic connector is electrically connected to a circuit structure inside the operating body, the second magnetic connector and the first magnetic connector are connected through magnetic attraction to conduct the circuit of the controller.

10. The controller according to claim 2, wherein the electrical connection assembly includes a first electrical connector and a second electrical connector, the first electrical connector is electrically connected to a circuit structure inside the mounting body, the second electrical connector is electrically connected to the circuit structure inside the operating body, wherein the first electrical connector is disposed on the mounting body and adjacent to the first magnetic connector, and the second electrical connector is disposed on the operating body and adjacent to the second magnetic connector.

11. The controller according to claim 3, wherein the electrical connection assembly includes at least one elastic connection component comprising a first elastic connector and a second elastic connector, the first elastic connector is disposed inside the connection slot and is electrically connected to a circuit structure inside the mounting body, the second elastic connector is disposed inside the connection buckle and is electrically connected to the a circuit structure inside the body.

12. The controller according to claim 4, wherein the electrical connection assembly includes at least one elastic connection component comprising a first elastic connector and a second elastic connector, the first elastic connector is disposed inside the first slide rail connector and is electrically connected to a circuit structure inside the mounting body, and the second elastic connector is disposed inside the second slide rail connector and is electrically connected to a circuit structure inside the operating body.

13. The controller according to claim 4, wherein the product body is a health care product used for at least one type of physical therapy for knee pads, waist pads, shoulder pads, elbow pads, neck pads, phototherapy, drug therapy, and vibration massage functions.

14. A controller of a product body, comprising:
a mounting body suitable for being mounted to the product body;
an operating body; and
a detachable connection assembly arranged on both of the mounting body and the operating body, and configured for forming a detachable connection between the mounting body and the operating body, and forming a detachably conducting a circuit between the mounting body and the operating body.

15. The controller according to claim 14, wherein the detachable connection assembly includes at least one magnetic connection component comprising a first magnetic connector and a second magnetic connector respectively disposed on the mounting body and the operating body, wherein the second magnetic connector and the first magnetic connector are capable of being magnetically attracted and being detachable from each other.

16. The controller according to claim 15, wherein the detachable connection assembly further includes at least one abutting bead connection component comprising a plurality of mounting grooves and a plurality of abutting bead, the mounting grooves are provided on the mounting body and located in the middle of the first magnetic connectors; the abutting beads are provided on the operating body, and located in the middle of the second magnetic connector, and are connected to the respective mounting grooves in a matching manner to form a detachable electrical connection to conduct the circuit between the mounting body and the operating body.

17. The controller according to claim 15, wherein the detachable connection assembly further includes at least one elastic connection component comprising a first elastic connector and a second elastic connector, the first elastic connector is provided on the mounting body and is electrically connected to the circuit structure inside the installation body, the second elastic connector is provided on the operating body and is electrically connected to the circuit inside the operating body, the first elastic connector and the second elastic connector are matched and connected to conduct the circuit between the operating body and the mounting body.

18. A controller, comprising:
a mounting base suitable for being mounted to a product body, the mounting base comprising a plurality of first magnetic buckles and a first slider, and the plurality of first magnetic buckles are electrically connected to a circuit in the product body; and
a controller main body comprising a plurality of second magnetic buckles electrically connected to a control circuit of the controller main body, and a second slider, the first magnetic buckles and the second magnetic buckles are magnetically connected, and the first slider and the second slider are engaged with each other.

19. The controller according to claim 18, wherein the first slider is provided with a sliding groove and a protruding block, the protruding block is along a length direction of the first slider, the second slider is inserted into the sliding groove and resists the protruding block.

20. The controller according to claim 19, wherein a groove is provided on the side of the second slider facing the protruding block, and the protruding block is capable of being received in the groove.
